(19) United States
(12) Patent Application Publication
(10) Pub. No.: US 2024/0320814 A1
(43) Pub. Date: Sep. 26, 2024

(54) DEFECT REDUCTION APPARATUS AND DEFECT REDUCTION METHOD

(71) Applicant: Samsung Electronics Co., Ltd., Suwon-si (KR)

(72) Inventors: Bongju LEE, Suwon-si (KR); Sangmin JUNG, Suwon-si (KR); Seunghwan YOO, Suwon-si (KR); Raehong YOUN, Suwon-si (KR); Namhoon LEE, Suwon-si (KR)

(73) Assignee: Samsung Electronics Co., Ltd., Suwon-si (KR)

(21) Appl. No.: 18/432,450

(22) Filed: Feb. 5, 2024

(30) Foreign Application Priority Data
Mar. 24, 2023 (KR) 10-2023-0039243
Apr. 17, 2023 (KR) 10-2023-0050249

(51) Int. Cl. G06T 7/00; G06T 3/403; G06T 5/40; G06T 5/92; G06T 7/13; G06T 7/136; G06T 7/60; H01L 21/67

(52) U.S. Cl. CPC G06T 7/0004; G06T 3/403; G06T 5/40; G06T 5/92; G06T 7/13; G06T 7/136; G06T 7/60; H01L 21/67288; G06T 2207/20036; G06T 2207/20132; G06T 2207/30148

(57) ABSTRACT

A defect inspection or reduction apparatus includes a chamber moving a substrate and having an inner space therein, a laser oscillation structure irradiating a laser beam to a processing area of the substrate, a mask positioned in the laser oscillation structure and processing the laser beam, a beam profiler obtaining a beam image for the laser beam passing through the mask, and a damage detector detecting a defect area of the mask and the laser beam from the beam image. The damage detector includes an image pre-processing department performing a pre-processing on the beam image that is obtained from the beam profiler, an image extraction department extracting a defect area of the beam image on which the pre-processing is performed, and an image detector detecting a defect of the beam image based on the defect area.

### CROSS-REFERENCE TO RELATED APPLICATION

This application is based on and claims priority under 35 U.S.C. § 119 to Korean Patent Application Nos. 10-2023-0039243, filed on Mar. 24, 2023 and 10-2023-0050249, filed on Apr. 17, 2023, in the Korean Intellectual Property Office, the disclosure of each of which are incorporated by reference herein in their entireties.

### BACKGROUND

Various example embodiments relate to a defect inspection and reduction apparatus and a defect inspection and reduction method.

In general, the semiconductor process may include an annealing process that heats a semiconductor substrate to remove or reduce the physical damage to the semiconductor substrate, and/or to activate various impurities included in the semiconductor substrate. The electrical properties and/or the mechanical properties of the semiconductor substrate can be improved by the annealing process.

The semiconductor substrate may be moved by the stage when performing the annealing process. Laser for heating the semiconductor substrate needs to or is expected to be irradiated precisely to improve the yield of the annealing process.

### SUMMARY

Various example embodiments provide a defect inspection/improvement apparatus and a defect inspection/improvement method in which defects of a mask for processing a laser are predicted and monitored based on a beam image, and a wafer is fabricated based upon the prediction and monitoring.

In addition, the problems to be solved or improved upon are not limited to the above-described problems, and some other features may be clearly understood by one of ordinary skill in the art from the following descriptions hereinafter.

According to various example embodiments, there is provided a defect reduction apparatus including a chamber configured to move a substrate and having an inner space therein, a laser oscillation structure configured to irradiate a laser beam to a processing area of the substrate, a mask positioned in the laser oscillation structure and configured to process the laser beam, a beam profiler configured to obtain a beam image for the laser beam passing through the mask, and a damage detector configured to detect a defect area of the mask and the laser beam from the beam image. The damage detector includes an image pre-processing department configured to perform a pre-processing on the beam image that is obtained from the beam profiler, an image extraction department configured to extract a defect area of the beam image on which the pre-processing is performed, and an image detector configured to detect a defect of the beam image based on the defect area.

Alternatively or additionally, there is provided a defect reduction apparatus including a chamber configured to move a substrate and having an inner space therein, a laser oscillation structure configured to irradiate a laser beam to a processing area of the substrate, a mask including an opening through which the laser beam is configured to pass and a plurality of mask edges blocking the laser beam, a beam profiler configured to obtain a beam image for the laser beam passing through the mask, and a damage detector configured to detect a defect area of the mask and the laser beam from the beam image. The damage detector includes an image pre-processing department configured to perform a pre-processing on the beam image obtained from the beam profiler, an image extraction department configured to extract a defect area of the beam image on which the pre-processing is configured to be performed, and an image detector configured to detect a defect of the beam image based on the defect area. The image pre-processing department is configured to normalize and upscale the beam image, and the laser beam is configured to be processed into a square by the mask.

Alternatively or additionally, there is provided a defect reduction method including irradiating a laser beam, processing the laser beam into a square shape, obtaining a beam image for the laser beam, performing a pre-processing on the beam image, extracting a defect area from the beam image on which the pre-processing is performed, detecting a defect of the beam image based on the defect area, and processing a substrate based on the laser beam The pre-processing on the beam image includes improving a resolution of the beam image by at least one of a linear interpolation, a deep learning model, and a curve fitting interpolation.

### BRIEF DESCRIPTION OF THE DRAWINGS

Various example embodiments will be more clearly understood from the following detailed description taken in conjunction with the accompanying drawings in which:

FIG. 1 is a conceptual view illustrating a defect inspection apparatus according to some example embodiments;

FIG. 2 is a cross-sectional view illustrating a mask according to some example embodiments;

FIG. 3 is a block diagram showing a defect inspection apparatus according to some example embodiments;

FIGS. 4A and 4B are flowcharts showing an image pre-processing process of a defect inspection method, according to some example embodiments;

FIGS. 5A to 5B are views illustrating a beam image according to some example embodiments;

FIG. 6 is a flowchart showing a method of extracting a defect area in a defect inspection method, according to some example embodiments;

FIGS. 7A to 7E are views illustrating a defect area for describing a defect inspection method according to some example embodiments;

FIG. 8 is a conceptual view illustrating a defect detection process of the defect inspection method according to some example embodiments; and

FIGS. 9A to 9D are conceptual views illustrating a defect prediction model according to some example embodiments.

### DETAILED DESCRIPTION OF VARIOUS EXAMPLE EMBODIMENTS

Hereinafter, some example embodiments are described in detail with reference to the accompanying drawings. The same reference numerals denote the same components in the drawings, and the descriptions on the same elements are omitted.

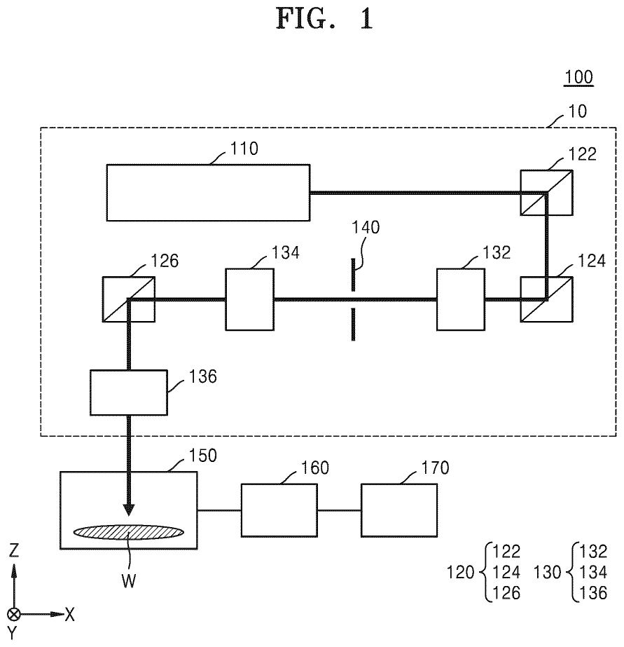

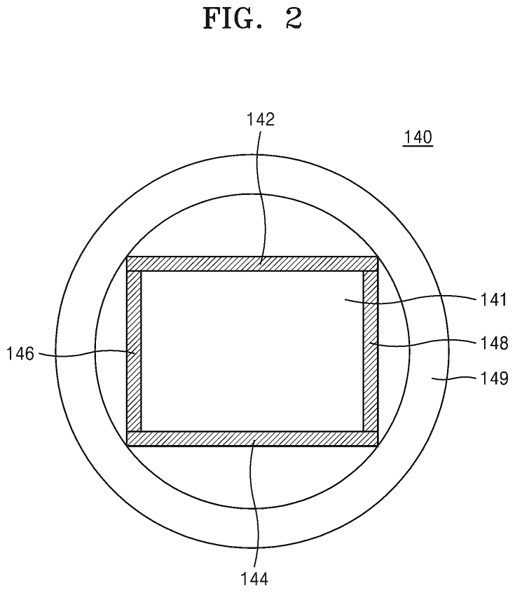

FIG. 1 is a conceptual view illustrating a defect inspection apparatus or a defect reduction apparatus according to some example embodiments. FIG. 2 is a cross-sectional view illustrating a mask according to some example embodiments.

Referring to FIGS. 1 and 2 together, a defect inspection or defect reduction apparatus 100 may include a chamber 150, a laser oscillation structure 10, a beam profiler 160, and a damage detector 170.

In some example embodiments, the defect inspection apparatus 100 may include a laser device that is used in an annealing process, for example a process to cure material and/or change the phase of a material and/or activate implanted ions. The chamber 150 may include an inner empty space in which a laser annealing process is performed. In addition, the chamber 150 may include a chuck on a bottom portion thereof. A substrate W, which is to be annealed, may be mounted on the chuck such as but not limited to an electrostatic chuck and/or a heated chuck and/or a ceramic chuck. The chamber 150 may further include an optical window that closes at least a portion of an upper end portion of the inner space thereof.

The optical window may include a material through which a laser beam passes.

The substrate W may be or include, for example, a semiconductor material such as single-crystal and/or doped silicon (Si). Alternatively or additionally, the substrate W may include a semiconductor element such as germanium (Ge), or a compound semiconductor such as silicon carbide (SiC), gallium arsenide (GaAs), indium arsenide (InAs), and indium phosphide (InP). The substrate W may include a conductive region, for example, a well doped with impurities. The substrate W may include various device isolation structures such as a shallow trench isolation (STI) structure. The substrate W may be a wafer, such as but not limited to a 150 mm or a 200 mm or a 300 mm-diameter wafer; however, example embodiments are not limited thereto.

The laser oscillation structure 10 may include the laser oscillator 110, the plurality of reflective mirrors 120, the laser transmission system 130, and the mask 140.

The laser oscillator 110 may generate a laser beam and emit the laser beam to the substrate W. The laser beam may be irradiated to the substrate W through the laser transmission system 130, which is described below, to thereby anneal the substrate W. In some example embodiments, an upper surface of the substrate W may be partially melted and recrystallized according as the laser beam is irradiated. In some example embodiments, when the substrate W includes amorphous silicon, at least a portion of the substrate W may be crystallized into polysilicon by the laser annealing. A plurality of reflective mirrors 120 may include a first reflective mirror 122, a second reflective mirror 124, and a third reflective mirror 126. In FIG. 1, the case where the plurality of reflection mirrors 120 include three reflection mirrors, that is, the first reflective mirror 122, the second reflective mirror 126, and the third reflective mirror 126 has been described but is not limited thereto. In some example embodiments, the laser transmission system 130 may include a first laser transmission unit 132, a second laser transmission unit 134, and a third laser transmission unit 136. In FIG. 1, the case where the laser transmission system 130 includes three transmission units, for example, the first laser transmission unit 132, the second laser transmission unit 134, and the third laser transmission unit 136 has been described but is not limited thereto.

Each of the first laser transmission unit 132, the second laser transmission unit 134, and the third laser transmission unit 136 may include a beam magnifying glass (not shown) and/or a band-reject filter. The beam magnifying glass may magnify the laser beam, which is irradiated from the laser oscillator 110 and reflected from the plurality of reflective mirrors 120, by a particular ration (such as a dynamically determined ratio, or alternatively, a preset ratio). The band-reject filter may reject light having a first wavelength and pass light having a second wavelength. That is, the band-reject filter may control the wavelength of the laser beam.

The first reflective mirror 122 may reflect the laser beam emitted from the laser oscillator 110 to the second reflective mirror 124. The second reflective mirror 124 may be positioned adjacent to the first reflective mirror 122 and may reflect the laser beam, which is reflected from the first reflective mirror 122, to the first laser transmission unit 132. Herein, the first reflective mirror 122, the second reflective mirror 124, the first laser transmission unit 132, and the second laser transmission unit 134 may be positioned on the same line. The mask 140 may be positioned between the first laser transmission unit 132 and the second laser transmission unit 134. The third reflective mirror 126 may reflect the laser beam passing through the second laser transmission unit 134 to the third laser transmission unit 136.

In some example embodiments, the mask 140 may be positioned in the laser oscillation structure 10. Alternatively or additionally in some example embodiments, the mask 140 may be positioned between the first laser transmission unit 132 and the second laser transmission unit 134. The mask 140 may include an open-type mask including an opening 141. The mask 140 may allow the laser beam to have a particular shape such as a dynamically determined shape, or alternatively a preset shape. The mask 140 may include an opening 141, a plurality of mask edges 142, 144, 146, and 148, and a body 149. The plurality of mask edges 142, 144, 146, and 148 and the body 149 may block the laser beam. The mask 140 may adjust a spot size or a shape of the laser beam.

The opening 141 may have a rectangular shape, e.g., a square shape. The laser beam transmitted from the first laser transmission unit 132 may pass through the opening 141 and reach the second laser transmission unit 134. Thus, the transmitting ratio of the laser beam may be improved by the opening 141 of the mask 140, to thereby minimize the loss of the laser beam.

The plurality of mask edges 142, 144, 146, and 148 may include a first mask edge 142, a second mask edge 144, a third mask edge 146, and a fourth mask edge 148. The first mask edge 142, the second mask edge 144, the third mask edge 146, and the fourth mask edge 148 may have a rectangular shape, e.g., a bar shape. In some example embodiments, the first mask edge 142, the second mask edge 144, the third mask edge 146, and the fourth mask edge 148 may have the same length. Alternatively or additionally in some example embodiments, the first mask edge 142 may intersect with the third mask edge at ninety degrees; example embodiments are not limited thereto.

In some example embodiments, the first mask edge 142 and the second mask edge 144 may have the same length and the third mask edge 146 and the fourth mask edge 148 may have the same length. In this case, the first mask edge 142 and the third mask edge 146 may have different lengths, and the second mask edge 144 and the fourth mask edge 148 may have different lengths. The body 149 of the mask 140 may have a circular shape. Each of the first mask edge 142, the second mask edge 144, the third mask edge 146, and the fourth mask edge 148 may be shaped into a sharp knife in a direction from the body 149 toward the opening 141. Each of the first mask edge 142, the second mask edge 144, the third mask edge 146, and the fourth mask edge 148 may include a metal material. The mask 140 may process the laser beam into an elaborate rectangular shape by the first mask edge 142, the second mask edge 144, the third mask edge 146, and the fourth mask edge 148.

The beam profiler 160 may obtain a beam image of the laser beam that has passed through the mask 140 and the third laser transmission unit 136 before the laser beam is irradiated to the substrate W. The beam profiler 160 may transfer the obtained beam image to the damage detector 170, as described below.

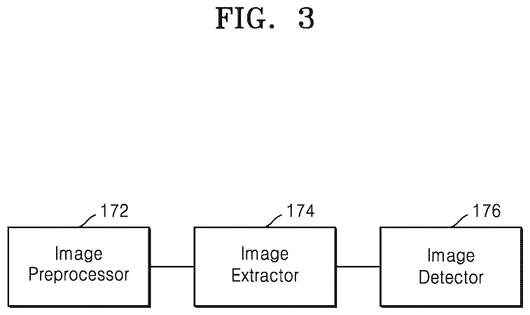

FIG. 3 is a block diagram showing a defect inspection apparatus according to some example embodiments.

Referring to FIGS. 1 and 3 together, the damage detector 170 may include an image pre-processing department 172, an image extraction department 174, and an image detector 176. The image pre-processing department 172 may perform pre-processing on the beam image obtained from the beam profiler 160. The image extraction department 174 may extract a defect area of the beam image on which the pre-processing is performed. The image detector 176 may detect a defect, such as a malformation, in the beam image based on the defect area. Herein, the defect may include a burr phenomenon in which a laser beam protrudes into a laser area in the shape of the beam image or a chipping phenomenon in which the laser beam protrudes from the laser area to a blocking area.

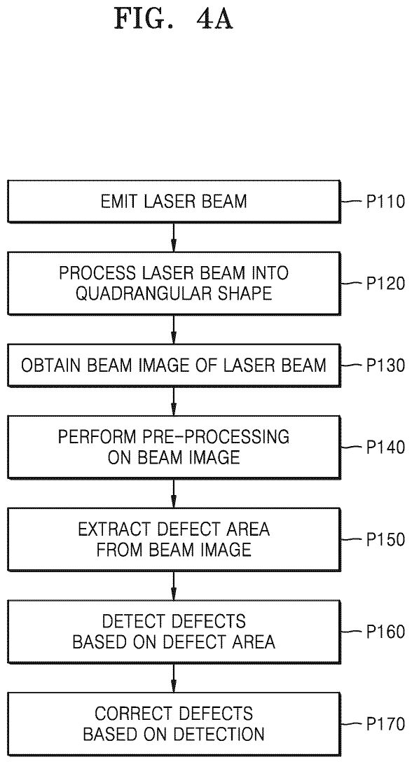

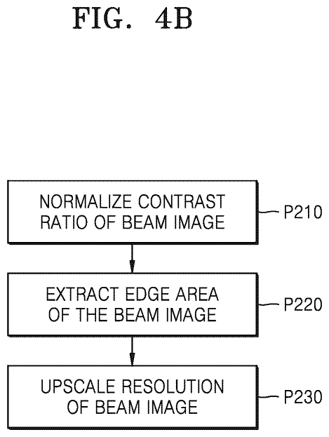

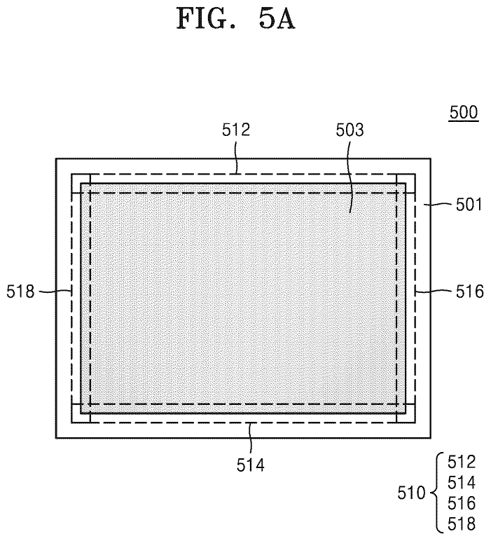

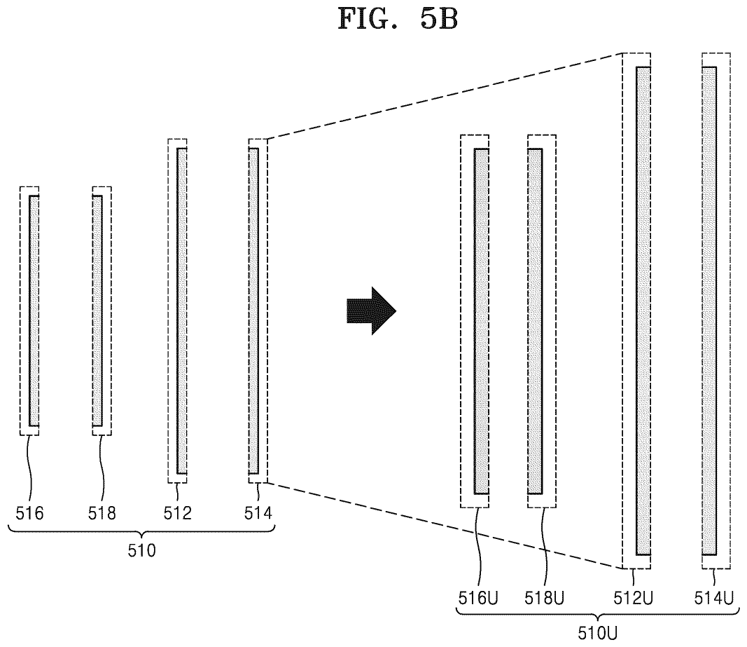

FIGS. 4A and 4B are flowcharts showing an image pre-processing process of a defect inspection or defect reduction method, according to some example embodiments. FIGS. 5A to 5B are views illustrating a beam image according to some example embodiments. The defect inspection method is described with reference to FIGS. 4A and 4B together with FIGS. 1 to 3, and the descriptions on the same elements in FIGS. 1 to 3 are briefly given or omitted.

Referring to FIGS. 3 and 4A together, the laser oscillator 110 may generate and emit the laser beam (P110). The mask 140 may process the laser beam into a quadrangular shape by the first to fourth mask edges 142, 144, 146, and 148 (P120). For example, the quadrangular shape may include a rectangular shape, such as but not limited to a square shape.

Before the laser beam is irradiated to the substrate W, the beam profiler 160 may obtain the beam image of the laser beam (P130). The beam profiler 160 may transmit the obtained beam image to the damage detector 170.

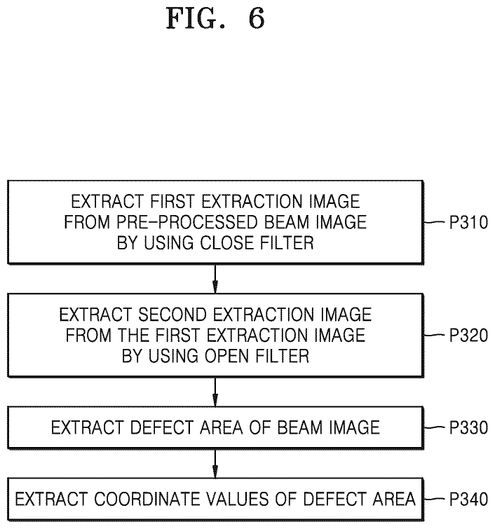

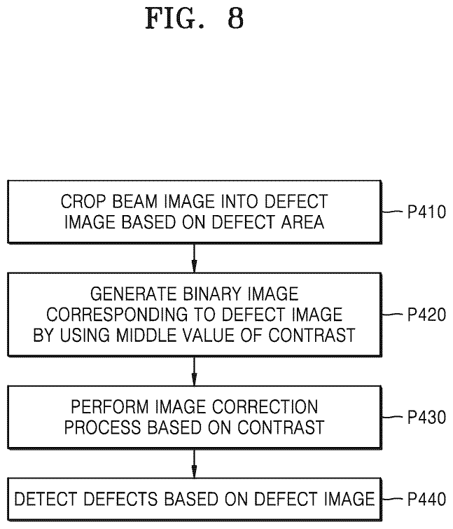

The image pre-processing department 172 of the damage detector 170 may perform pre-processing on the beam image (P140). The image extraction department 174 may extract a defect area of the beam image on which the pre-processing is performed (P150). The image detector 176 may detect a defect in the beam image based on the defect area (P160). Based on the detection of the defect, the substrate and/or a subsequent substrate may be fabricated (P170). The pre-processing on the beam image is described in detail with reference to FIG. 4B hereinafter. The other operations, which are subsequent to operation P140, are to be continuously described in detail with reference to FIGS. 6 and 8.

Referring to FIGS. 1, 2, and 4B together, the pre-processing on the beam image may be performed by normalizing a contrast ratio of the beam image at first (P210). Specifically, a histogram may be calculated based on pixel values of the beam image. The histogram is a graph of the distribution of contrast values of each pixel of the beam image.

Then, the beam image may be normalized based on the histogram. For example, the beam image may be normalized based on a middle value such as an average value or central value or median value (for example, a threshold value) of peak values in the laser area, which is a passing area of the laser beam through the opening 141 of the mask 140, and in the blocking area which is a block area of the laser beam by the mask 140. The beam image may be coded into binary digits, such as a two-level value, at each pixel thereof by the processes described above. Specifically, all values greater than the middle value may be changed into a single pixel value, and all values less than the middle value may be changed into another single pixel value. Herein, the peak value may indicate a contrast value which the largest number of pixels having the same contrast has in the laser area or the blocking area. By normalizing the beam image to a binary image based on the histogram, the defect may be inspected based on a clearer image.

Referring to FIGS. 2, 4B, and 5A together, after normalizing the contrast ratio of the beam image 500, an edge area of the beam image 500 may be extracted (P220).

Specifically, a plurality of edge areas 512, 514, 516, and 518, which correspond to the first to fourth mask edges 142, 144, 146, and 148, respectively, may be extracted as a first edge image 510 to inspect each of the first to fourth mask edges 142, 144, 146, and 148. The plurality of edge areas 512, 514, 516, and 518 may include a first edge area 512 for the first edge 142, the second edge area 514 for the second edge 144, the third edge area 516 for the third edge, and the fourth edge area 518 for the fourth edge 148. The plurality of edge areas 512, 514, 516, and 518 may include a large area surrounding the first to fourth mask edges 142, 144, 146 and 148. Herein, the plurality of edge areas 512, 514, 516, and 518 may be extracted by cropping some areas (e.g., the plurality of edge areas) of the beam image 500.

Referring to FIGS. 4B and 5B together, after extracting the plurality of edge areas 512, 514, 516, and 518, the resolution of each edge area 512, 514, 516, and 518 of the beam image 500 may be upscaled (P230). Specifically, the first edge image 510 including the edge areas 512, 514, 516, and 518 may be upscaled and converted into a second edge image 510U.

Thus, the second edge image 510U may include a first high-definition edge area 512U corresponding to the first edge area 512, a second high-definition edge area 514U corresponding to the second edge area 514, a third high-definition edge area 516U corresponding to the third edge area 516, and a fourth high-definition edge area 518U corresponding to the fourth edge area 518. For example, the second edge image 510U may include an enlarged image that is larger than the first edge image 510. For example, in operation P230, the first edge image 510 may be enlarged and the resolution of the first edge image 510 may be improved, to thereby convert the first edge image 510 into the second edge image 510U.

The first edge image 510 may be converted into the second edge image 510U by any one or more of a linear interpolation, a deep learning model, or a curve fitting interpolation (e.g., a polynomial fitting model such as a quadratic and/or cubic fitting model). The deep learning model may include a model in which learning is performed for converting the inputs such as the beam image 500 and the learning high-definition beam image into the outputs such as the high-definition beam image.

In the deep learning model, a feature vector may be extracted from the first edge image 510 and the second edge image 510U of which the resolution is upscaled based on the feature vector may be output. In some example embodiments, the deep learning model may include various nerve network structures such as one or more of a super resolution convolutional neural network (SRCNN), a fast SRCNN (FSRCNN), an efficient sub-pixel convolutional neural network (ESPCN), very deep super resolution (VDSR), a deeply recursive convolutional network (DRCN), SRResNet, a deep recursive residual network (DRRN), an enhanced deep super residual (EDSR), DenseSR, a memory network (MemNet), a generative adversarial network (GAN), deep blind video super resolution (DBVSR), a local global fusion network (LGFN), dynamic adaptive blind video super resolution (DynaVSR), and iSeeBetter.

In this way, some data (e.g., location, height, width, size) of the defect area and/or damage area may be obtained from an image having a resolution higher than that of the image camera of the beam profiler 160. Thus, the defect of the mask 140 may be inspected more precisely by the defect inspection apparatus and the defect inspection method according to some example embodiments.

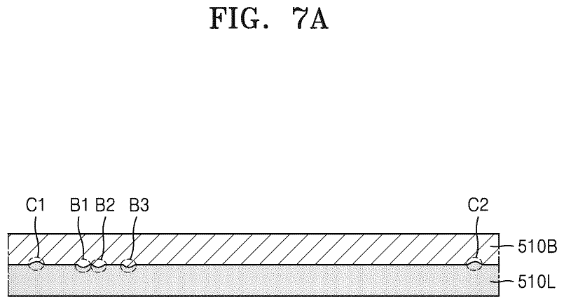

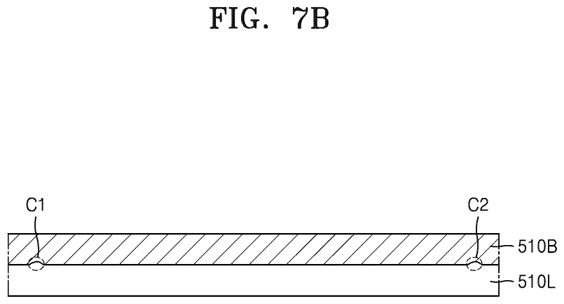

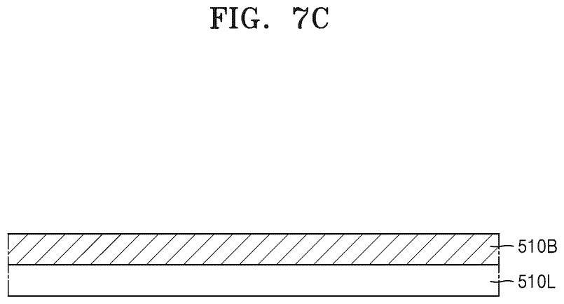

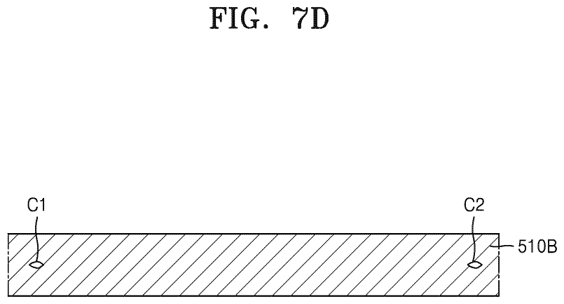

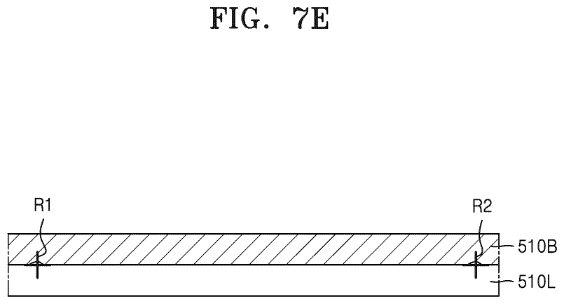

FIG. 6 is a flowchart showing a method of extracting a defect area in a defect inspection method, according to various example embodiments. FIGS. 7A to 7E are views illustrating a defect area for describing a defect inspection method according to various example embodiments. FIG. 7A is a view illustrating the defect area in a portion of the second edge image according to some example embodiments. FIG. 7B is a view illustrating a first extracted image according to some example embodiments. FIG. 7C is a view illustrating a second extracted image according to some example embodiments. FIG. 7D is a view illustrating a chipping area according to some example embodiments.

Referring to FIGS. 6 and 7A together, a plurality of defects may be found between the blocking area 510B and the laser area 510L. The plurality of defects may include burr defects B1, B2, and B3 and chipping defects C1 and C2. Although three burr defects and two chipping defects are illustrated, example embodiments are not limited thereto. The burr defects B1, B2, and B3 may refer to defect caused by the burr phenomenon described above. In addition, the burr defects B1, B2, and B3 may occur on at least a portion of the laser area 510L at which the laser beam is blocked. The chipping defects C1 and C2 may refer to defects caused by the chipping phenomenon described above. In addition, the chipping defects C1 and C2 may occur on at least a portion of the blocking area 510B at which the laser beam is irradiated.

In FIG. 7A, the chipping defects are illustrated as a first chipping defect C1 and a second chipping defect C2 and the burr defects are illustrated as a first burr defect B1, a second burr defect B2, and a third burr defect B3, but the chipping defects and the burr defects are not limited thereto.

Referring to FIGS. 6 and 7B together, for the extraction of the defect area in the defect inspection method, a first extraction image may be extracted from the pre-processed beam image by using a close filter based on the morphology operation (P310). For example, the first extraction image may be generated without a burr defect by removing the burr defects B1, B2, and B3 with the close filter. Therefore, the noise in the laser area 510L may be removed by the close filter.

Referring to FIGS. 6 and 7C together, after generating the first extraction image, a second extraction image may be extracted from the first extraction image by an open filter based on the morphology operation (P320). The chipping defects C1 and C2 may be removed by the open filter. Therefore, the second extraction image may be extracted without any defects (e.g., without any of burr defects B1, B2, and B3 and chipping defects C1 and C2), and thus, the second extraction image may reflect both of the laser area 510L and the blocking area 510B.

In some example embodiments, the extracting of the first extraction image by using the close filter in operation P310 and the extracting of the second extraction image by using the open filter in operation P320 may be repeated several times. For example, the close filter and/or the open filter may be repeatedly applied to the beam image several times. In some example embodiments, the kernel used in the close filter and/or open filter may be in any one of square, rectangular, and cross shapes.

Referring to FIGS. 6 and 7D together, after extracting the second extraction image, a defect area of the beam image may be extracted (P330). Specifically, the laser area 510L and the burr defects B1, B2, and B3 may be removed by subtracting the second extraction image shown in FIG. 7C from the defect area in a portion of the second edge image shown in FIG. 7A. Accordingly, as shown in FIG. 7D, an image of another defect area including the blocking area 510B and the chipping defects C1 and C2 may be generated. In addition, the image of the burr defects B1, B2, and B3 may be generated and coordinate values of the burr defects B1, B2, and B3 may be extracted when subtracting the image for some defect areas of the second edge image in FIG. 7A from the first extracted image of FIG. 7B.

Referring to FIGS. 6, 7D, and 7E together, after extracting the defect area, coordinate values R1 and R2 for the defect area in the beam image may be extracted based on the center position of the chipping defects C1 and C2 of the defect area (P340). In some example embodiments, a first coordinate value R1 may correspond to the first chipping defect C1 and the second coordinate value R2 may correspond to the second chipping defect C2. The first coordinate value R1 and the second coordinate value R2 may include an X-axis coordinate value and a Y-axis coordinate value, respectively. In some example embodiments, the coordinate values may be cartesian coordinates; however, example embodiments are not limited thereto; for example in some example embodiments the coordinate values may be polar coordinates.

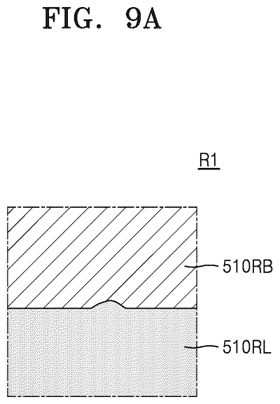

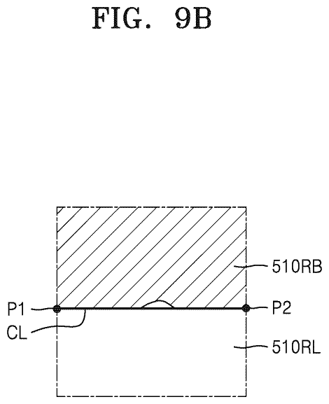

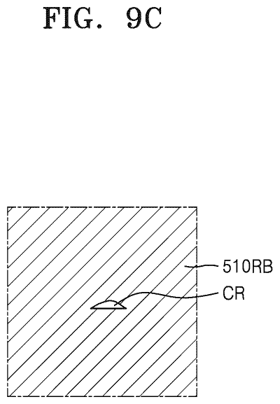

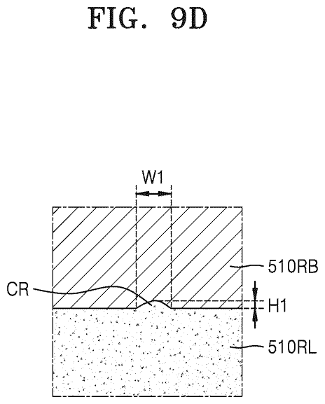

FIG. 8 is a conceptual view illustrating a defect detection process of the defect inspection method according to some example embodiments. FIGS. 9A to 9D are conceptual views illustrating a defect prediction model according to some example embodiments.

Referring to FIG. 8 and FIG. 9A together, the beam image may be cut into a defect image R1 based on the coordinate values of the defect area that is obtained in operation P340 (P410). The defect image R1 may include an adjacent laser area 510RL that is adjacent to the defect in the area irradiated with the laser beam passing through the mask and an adjacent blocking area 510RB that is adjacent to the defect in the area in which the laser beam is blocked by the mask. The first chipping defect may be between the adjacent laser area 510RL and the adjacent blocking area 510RB and may be shown as a convex shape protruding from the adjacent laser area 510RL to the adjacent blocking area 510RB.

The defect detection process of the defect inspection method according to the embodiment may crop the beam image into a rectangle, such as a square, of a particular size around the coordinate value of the defect area (P410). The crop image may correspond to the defect image R1. FIG. 9A shows the defect image of the chipping defect, but the defect image of the burr defect is obtained by the same process described above.

Referring to FIG. 8 and FIG. 9B together, after the beam image is cut into the defect image R1, the defect image may be generated into a binary image by using a middle value between the contrast value of the adjacent laser area 510RL and the contrast value of the adjacent blocking area 510RB (P420). Thus, although the resolution of the defect image R1 is low, the boundary surface may be accurately shown between the adjacent laser area 510RL and the adjacent blocking area 510RB in the defect image R1.

After generating the binary image, an image correction process may be performed on the boundary image based on the contrast of pixels of the adjacent laser area 510RL and the adjacent blocking area 510RB (P430). Specifically, the image correction process may designate a first end of the boundary between the adjacent laser area 510RL and the adjacent blocking area 510RB as a first point P1 and a second end of the boundary opposite to the first end as a second point P2.

Referring to FIGS. 8, 9B, and 9C together, a boundary line CL may be generated by connecting the first point P1 and the second point P2, and the contrast value of the adjacent laser area 510RL, which is opposite to the adjacent blocking area 510RB with respect to the boundary line CL, may be darkened. In some example embodiments, the pixel values under the boundary line CL may be changed to about 0 in a direction opposite to the adjacent blocking area 510RB, so that the pixels under the boundary line CL may be darkened. The defect image may be converted by the image correction process, and only a specific chipping defect area CR is shown in the adjacent blocking area 510RB. When performing the defect inspection on the burr defect, the contrast value of the adjacent blocking area 510RB, which is opposite to the adjacent laser area 510RL with respect to the boundary line CL, may be brightened. The pixel values may be changed highest, so that the pixels under the boundary line CL may be brightened.

Accordingly, the boundary line CL may be determined between the adjacent laser area 510RL and the adjacent blocking area 510RB, and then, the image correction process may be performed on any one side of the adjacent laser area 510RL and the adjacent blocking area 510RB with respect to the boundary line CL, so that the defects (such as, the chipping defect and/or the burr defect) may be detected although the laser area in the beam image is twisted or distorted.

Referring to FIGS. 8, 9C and 9D together, after performing the image correction process, the chipping defect CR may be detected from the defect image on which the image correction process has been performed (P440). Herein, the detection of the chipping defect CR may include the detection of various defect data, such as a height H1, a width W1, and a detected number of a specific chipping defect CR, as well as the coordinate values of the specific chipping defects CR.

Referring back to FIG. 1, after detecting the defect data, the damage detector 170 may determine whether to generate an alarm based on the defect data. Specifically, the damage detector 170 may calculate a total defect score based on the position of defects, the number of defects, the type of defects (e.g., burr defect or chipping defect), and the size of defects (e.g., defect area, defect width and/or defect height).

In some example embodiments, the damage detector 170 may generate an alarm when the total defect score exceeds a particular (such as a dynamically determined or predetermined) defect threshold. In some example embodiments, the damage detector 170 may stop the semiconductor process (e.g., the annealing process) on the substrate W when the total defect score exceeds the defect threshold. For example, the laser oscillation structure 10 may stop irradiating the laser beam. In some example embodiments, when the total defect score is less than or equal to the defect threshold, the damage detector 170 may control the semiconductor process to be performed on the substrate W without an alarm. In such a case, the laser beam may be irradiated on the substrate W, to thereby perform the annealing process on the substrate W. Accordingly, the defects that may occur in semiconductor devices may be prevented or reduced in likelihood of occurrence in advance by detecting and monitoring the defects of the mask from beam images in advance, to thereby improve the stability and/or reliability of the semiconductor devices.

Some example embodiments have been disclosed in the drawings and specification as described above. Although various example embodiments have been described by using specific terms in this specification, they are only used for the purpose of explaining the technical idea of the disclosure, and are not used to limit the scope of the disclosure described in the claims. Therefore, those of ordinary skill in the art will understand that various modifications and equivalent other embodiments are obtainable therefrom. Therefore, the true technical scope of protection should be determined by the technical idea of the appended claims.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

While inventive concepts have been particularly shown and described with reference to embodiments thereof, it will be understood that various changes in form and details may be made therein without departing from the spirit and scope of the following claims.

Furthermore, example embodiments are not necessarily mutually exclusive with one another.

For example, some example embodiments may include one or more features described with reference to one or more figures, and may also include one or more features described with reference to one or more other figures.

What is claimed is:

1. A defect inspection apparatus comprising:
a chamber configured to move a substrate and having an inner space therein;
a laser oscillation structure configured to irradiate a laser beam to a processing area of the substrate;
a mask positioned in the laser oscillation structure and configured to process the laser beam;
a beam profiler configured to obtain a beam image for the laser beam passing through the mask; and
a damage detector configured to detect a defect area of the mask and the laser beam from the beam image,
wherein the damage detector includes
an image pre-processing department configured to perform a pre-processing on the beam image that is obtained from the beam profiler,
an image extraction department configured to extract a defect area of the beam image on which the pre-processing is performed, and
an image detector configured to detect a defect of the beam image based on the defect area.

2. The defect inspection apparatus of claim 1, wherein
the mask includes an opening through which the laser beam is configured to pass and a plurality of mask edges configured to block the laser beam, and
the mask is configured to process the laser beam into a square.

3. The defect inspection apparatus of claim 1, wherein
the image pre-processing department is configured to calculate a histogram based on pixel values of the beam image, and
to normalize the beam image based on the histogram.

4. The defect inspection apparatus of claim 1, wherein
the image pre-processing department is configured to extract a plurality of edge areas of the beam image as a first edge image and to upscale the first edge image into a second edge image.

5. The defect inspection apparatus of claim 4, wherein
the image pre-processing department is configured to convert the first edge image into a second edge image by at least one of a linear interpolation, a deep learning model, or a curve fitting interpolation.

6. The defect inspection apparatus of claim 1, wherein
the image extraction department is configured to extract a first extraction image from the pre-processed beam image by using a close filter based on a morphology operation, and
to extract a second extraction image from the first extraction image by an open filter based on the morphology operation.

7. The defect inspection apparatus of claim 6, wherein
the image extraction department is configured to extract the defect area by one of removing the pre-processed beam image from the first extraction image and removing the second extraction image from the pre-processed beam image.

8. The defect inspection apparatus of claim 7, wherein
the image extraction department is configured to extract coordinate values of the defect area and to transfer the coordinate values to the image detector.

9. The defect inspection apparatus of claim 1, wherein the image detector is configured to
crop the beam image into a defect image based on the defect area, and
generate a binary image by using a middle value between contrasts of the defect image as a threshold value.

10. The defect inspection apparatus of claim 9, wherein
the image detector is configured to perform an image correction process based on the contrast of the defect image.

11. The defect inspection apparatus of claim 10, wherein
the image detector is configured to detect at least one of a width, a height, and a size of the defect in a defect shape of the defect image in which the image correction process is performed.

12. A defect inspection apparatus comprising:
a chamber configured to move a substrate and having an inner space therein;
a laser oscillation structure configured to irradiate a laser beam to a processing area of the substrate;
a mask including an opening through which the laser beam is configured to pass and a plurality of mask edges configured to block the laser beam;
a beam profiler configured to obtain a beam image for the laser beam passing through the mask; and
a damage detector configured to detect a defect area of the mask and the laser beam from the beam image,
wherein the damage detector includes
an image pre-processing department configured to perform a pre-processing on the beam image that is obtained from the beam profiler,
an image extraction department configured to extract a defect area of the beam image on which the pre-processing is performed, and
an image detector configured to detect a defect of the beam image based on the defect area, and
wherein the image pre-processing department is configured to normalize and upscale the beam image, and
the mask is configured to process the laser beam into a square.

13. The defect inspection apparatus of claim 12, wherein the image pre-processing department is configured to
calculate a histogram based on pixel values of the beam image, and
normalize the beam image based on the histogram,
wherein the defect reduction apparatus is configured to have a plurality of edge areas extracted from the normalized beam image as a first edge image, and to upscale the first edge image into a second image.

14. The defect inspection apparatus of claim 12, wherein
the image pre-processing department is configured to improve a resolution of the beam image by at least one of a linear interpolation, a deep learning model, or a curve fitting interpolation.

15. The defect inspection apparatus of claim 12, wherein the image pre-processing department is configured to
extract a first extraction image from the pre-processed beam image by using a close filter based on a morphology operation, and
extract a second extraction image from the first extraction image by using an open filter based on the morphology operation,
the image pre-processing department is configured to extract a chipping area by removing the second extraction image from the pre-processed beam image, and
to extract a burr area is extracted by removing the pre-processed beam image from the first extraction image.

16. The defect inspection apparatus of claim 12, wherein
the damage detector is configured to generate an alarm in response to a total defect score, which is calculated based on a defect number and a defect size, exceeds a defect threshold.

17. A defect inspection method comprising:
irradiating a laser beam;
processing the laser beam into a square shape;
obtaining a beam image for the laser beam;
performing a pre-processing on the beam image;
extracting a defect area from the beam image on which the pre-processing is performed;
detecting a defect of the beam image based on the defect area; and
processing a substrate based on the laser beam,
wherein the pre-processing on the beam image includes improving a resolution of the beam image by at least one of a linear interpolation, a deep learning model, and or a curve fitting interpolation.

18. The defect inspection method of claim 17, wherein
performing pre-processing on the beam image includes:
normalizing the beam image based on a histogram of pixel values of the beam image;
extracting a plurality of edge areas of the beam image as a first edge image; and
upscaling the first edge image to a second edge image.

19. The defect inspection method of claim 17, wherein
extracting the defect area from the beam image includes:
extracting a first extraction image from the beam image on which the pre-processing is performed by using a close filter based on a morphology operation;
extracting a second extraction image from the first extraction image by using an open filter based on the morphology operation; and
extracting coordinate values of the defect area by using any one extraction image of the pre-processed beam image, the first extraction image, and the second extraction image.

20. The defect inspection method of claim 17, wherein
detecting the defect of the beam image based on the defect area includes:
obtaining defect images based on the defect area of the beam image;
generating a binary image by using a threshold value that is based on a middle value between contrasts of the defective images;
performing an image correction process on the binary image based on the contrasts of the defective images; and
detecting at least one of a width, a height, and a size of the defect from a defect shape of the defect image on which the image correction process is performed.
